(19) United States
(12) Patent Application Publication
(10) Pub. No.: US 2025/0215574 A1
(43) Pub. Date: Jul. 3, 2025

(54) SEMICONDUCTOR TREATMENT LIQUID FOR REMOVING RUTHENIUM SILICIDE

(71) Applicant: TOKUYAMA CORPORATION, Yamaguchi (JP)

(72) Inventors: Yuzan SUZUKI, Yamaguchi (JP); Yuki KIKKAWA, Yamaguchi (JP)

(73) Assignee: TOKUYAMA CORPORATION, Yamaguchi (JP)

(21) Appl. No.: 18/999,298

(22) Filed: Dec. 23, 2024

(30) Foreign Application Priority Data
Dec. 27, 2023 (JP) 2023-221101

(51) Int. Cl. C23F 1/26; H01L 21/3213

(52) U.S. Cl. CPC C23F 1/26; H01L 21/32134

(57) ABSTRACT

A semiconductor treatment liquid for removing ruthenium silicide from a substrate containing ruthenium silicide, the semiconductor treatment liquid for ruthenium silicide removal containing (i) at least one selected from the group consisting of hypochlorous acid, hypobromous acid, periodic acid, and ions thereof, (ii) at least one selected from the group consisting of hydrogen fluoride and a fluoride ion, and (iii) an onium ion.

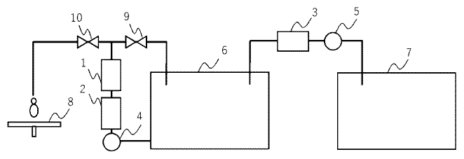

### TECHNICAL FIELD

The present invention relates to a semiconductor treatment liquid for removing ruthenium silicide.

### BACKGROUND ART

In a semiconductor element, a wiring layer is formed for the purpose of extracting an electrical signal generated by a transistor to the outside. As semiconductor elements are made finer year by year, the use of a material with low electromigration resistance or high resistance causes a decrease in reliability of the semiconductor element or inhibits high-speed operations. Therefore, a material with high electromigration resistance and a low resistance value as a wiring material is desired.

As such materials having high electromigration resistance and a low resistance value, for example, aluminum and copper have been used, and recently, tungsten, cobalt, molybdenum, and ruthenium have been examined. Among these materials, ruthenium exhibits higher electromigration resistance and can reduce the resistance value of wiring, and for this reason, ruthenium in particular is attracting attention as a wiring material for semiconductor elements based on a design rule of 10 nm or less. In addition, even in cases in which copper is used as a wiring material, the use of ruthenium as a barrier metal for the copper wiring is also being examined.

Forming a wiring layer in a semiconductor element includes a step of processing a wiring material, and dry or wet etching is used in this step. Amongst dry and wet etching, studies are advancing for the application of wet etching, which has a high throughput and a lower apparatus cost than dry etching, in next-generation wiring formation processes.

Furthermore, in recent years, ruthenium silicide has attracted attention as a wiring material or a barrier metal. Ruthenium silicide has a feature of suppressing the movement of oxygen from a silicon oxide film to a metal wiring, and thus applications of ruthenium silicide as a barrier metal are particularly anticipated. Ruthenium silicides are Ru—Si alloys and are known to have structures such as RuSi, RuSi₂, Ru₂Si₃, Ru₂Si, or Ru₄Si₃. In particular, RuSi₂ has a stable semiconductor phase of a FeSi-type structure and a high-temperature metal phase of a CsCl-type structure, and therefore the use of RuSi₂ as a thermal conversion material is anticipated. Thermal conversion materials are materials that generate electricity through a temperature difference, and such materials have a characteristic of being able to convert heat into electricity.

However, with an etching solution for ruthenium or a known metal, the etching rate of ruthenium silicide is not sufficient, and it is difficult to effectively remove the ruthenium silicide. Therefore, a demand has existed for an etching solution that can effectively remove ruthenium silicide.

Patent Document 1 proposes, as an etching solution for ruthenium silicide, a solution containing calcium hypochlorite and hydrofluoric acid. Patent Document 1 indicates that the solution can remove a 1000 Å ruthenium silicide film through treatment for 3 minutes. As the etching mechanism thereof, it is presumed that etching is carried out in following cycle. First, a silicon oxide film on the surface layer is removed by the hydrofluoric acid in the solution, and ruthenium atoms and silicon atoms are exposed. Next, an oxidizing agent in the solution oxidizes and dissolves the ruthenium and oxidizes the silicon to form silicon oxide. Subsequently, the hydrofluoric acid removes the silicon oxide in the solution.

### PRIOR ART DOCUMENTS

### Patent Document

Patent Document 1: JP 2004-533712 Å

### SUMMARY OF INVENTION

However, when the etching solution described in Patent Document 1 was used, it was confirmed that the silicon substrate on the back surface was also etched, and that the silicon substrate was damaged to such an extent that the damage could be visually confirmed. Observation of the damaged area with a scanning electron microscope confirmed the occurrence of hillock defects, indicating that the silicon was anisotropically etched. As the presumed mechanism, it is thought that a silicon oxide film is formed on the silicon substrate by the oxidizing agent in the solution, and the formed silicon oxide film is etched by the hydrofluoric acid. Under these circumstances, a semiconductor treatment liquid that can remove ruthenium silicide without damaging the silicon substrate is desired.

Accordingly, an object of the present invention is to provide a semiconductor treatment liquid that can remove ruthenium silicide while suppressing damage to a silicon substrate.

The present inventors conducted diligent research to solve the above problems.

As a result, the inventors discovered that ruthenium silicide can be removed while suppressing damage to a silicon substrate by using a semiconductor treatment liquid for ruthenium silicide removal, the semiconductor treatment liquid containing:
(i) at least one selected from the group consisting of hypochlorous acid, hypobromous acid, periodic acid, and ions thereof;
(ii) at least one selected from the group consisting of hydrogen fluoride and a fluoride ion; and
(iii) an onium ion.

The present invention was completed based on this finding.

That is, the present invention is configured as follows.

<1> A semiconductor treatment liquid used for removing ruthenium silicide from a substrate containing ruthenium silicide, the semiconductor treatment liquid for ruthenium silicide removal containing the following components:
(i) at least one selected from the group consisting of hypochlorous acid, hypobromous acid, periodic acid, and ions thereof;
(ii) at least one selected from the group consisting of hydrogen fluoride and a fluoride ion; and
(iii) an onium ion.

<2> The semiconductor treatment liquid for ruthenium silicide removal according to <1>, wherein the component (i) is at least one selected from the group consisting of hypochlorous acid and a hypochlorite ion.

<3> The semiconductor treatment liquid for ruthenium silicide removal according to <1> or <2>, wherein a total concentration of the component (i) in the semiconductor treatment liquid is 0.001 mol/L to 0.50 mol/L in terms of halogen element content.

<4> The semiconductor treatment liquid for ruthenium silicide removal according to any of <1> to <3>, wherein a total concentration of the component (ii) in the semiconductor treatment liquid is 0.001 mol/L to 10.0 mol/L in terms of fluorine element content.

<5> The semiconductor treatment liquid for ruthenium silicide removal according to any of <1> to <4>, wherein a total concentration of the component (iii) in the semiconductor treatment liquid is 0.001 mol/L to 10.0 mol/L.

<6> The semiconductor treatment liquid for ruthenium silicide removal according to any of <1> to <5>, wherein the semiconductor treatment liquid has a pH of 0.0 to 10.0 at 25° C.

<7> The semiconductor treatment liquid for ruthenium silicide removal according to any of <1> to <6>, wherein the component (iii) is an onium ion represented by the following Formula (1):

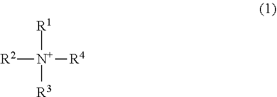

wherein, R¹, R², R³, and R⁴ each independently represent an alkyl group having a carbon number from 1 to 9, an allyl group, an aralkyl group having an alkyl group having a carbon number from 1 to 9, or an aryl group; at least one hydrogen of the aryl group in the aralkyl group and in the ring of the aryl group is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9; and in these groups, at least one hydrogen is optionally substituted with fluorine, chlorine, bromine, or iodine.

<8> A method for manufacturing a semiconductor element, the method including a step of bringing a substrate containing ruthenium silicide into contact with the semiconductor treatment liquid according to any of <1> to <7>, thereby etching the ruthenium silicide.

### Advantageous Effects of Invention

According to the present invention, a semiconductor treatment liquid for ruthenium silicide removal can be provided whereby ruthenium silicide can be removed while suppressing damage to a silicon substrate.

### BRIEF DESCRIPTION OF DRAWINGS

The FIGURE is a diagram schematically illustrating equipment used in an etching step of a method for manufacturing a semiconductor element.

### DESCRIPTION OF EMBODIMENTS

Embodiments of the present invention are described in detail below, but as long as the gist of the present invention is observed, the present invention is not limited to the details described below. In addition, the present invention can be modified and implemented in any manner within a scope that does not depart from the gist of the present invention.

In the present specification, a numerical range expressed using the term “to” refers to a range including the numerical values described before and after “to” as the lower limit and the upper limit, respectively. Thus, the expression “A to B” means A or more and B or less. Further, when numerical ranges are described in a stepwise manner, the upper limit and the lower limit of each numerical range can be optionally combined.

In addition, in the present specification, the expression “A or B” can be read as “at least one selected from the group consisting of A and B”.

### (Semiconductor Treatment Liquid)

A semiconductor treatment liquid (hereinafter, also referred to as a treatment liquid) of the present embodiment is a semiconductor treatment liquid used for removing ruthenium silicide from a substrate containing ruthenium silicide, the semiconductor treatment liquid containing the following components:
(i) at least one selected from the group consisting of hypochlorous acid, hypobromous acid, periodic acid, and ions thereof;
(ii) at least one selected from the group consisting of hydrogen fluoride and a fluoride ion; and
(iii) an onium ion.

### (Oxidizing Agent)

The semiconductor treatment liquid of the present embodiment contains (i) at least one selected from the group consisting of hypochlorous acid, hypobromous acid, periodic acid, and ions thereof.

These halogen oxyacids and ions act as oxidizing agents for removing ruthenium silicide. These oxidizing agents have a function of oxidizing and dissolving ruthenium atoms in the ruthenium silicide and a function of oxidizing silicon atoms in ruthenium silicide to form silicon oxide. In the present specification, the above-mentioned halogen oxyacids and ions may be hereinafter collectively referred to simply as an oxidizing agent.

The total concentration of the oxidizing agent contained in the semiconductor treatment liquid of the present embodiment is not particularly limited. However, from the viewpoint of sufficiently oxidizing and dissolving the ruthenium silicide, the total concentration of the oxidizing agent in terms of halogen element content relative to the total amount of the treatment liquid is preferably 0.001 mol/L or more and 0.50 mol/L or less, more preferably 0.005 mol/L or more and 0.20 mol/L or less, and particularly preferably 0.01 mol/L or more and 0.10 mol/L or less.

When hypobromous acid, a hypobromite ion, hypochlorous acid, and/or a hypochlorite ion is selected as the oxidizing agent contained in the semiconductor treatment liquid of the present embodiment, the total concentration of hypobromous acid, a hypobromite ion, hypochlorous acid, and a hypochlorite ion is not particularly limited. However, from the viewpoint of sufficiently oxidizing and dissolving the ruthenium silicide, the total concentration in terms of halogen element content relative to the total amount of the treatment liquid is preferably 0.001 mol/L or more and 0.50 mol/L or less, more preferably 0.005 mol/L or more and 0.20 mol/L or less, and particularly preferably 0.01 mol/L or more and 0.10 mol/L or less.

When periodic acid and/or a periodate ion is selected as the oxidizing agent contained in the semiconductor treatment liquid of the present embodiment, the total concentration of periodic acid and a periodate ion is not particularly limited. However, from the viewpoint of sufficiently oxidizing and dissolving the ruthenium silicide, the total concentration in terms of elemental iodine content relative to the total amount of the treatment liquid is preferably 0.001 mol/L or more and 0.50 mol/L or less, more preferably 0.005 mol/L or more and 0.20 mol/L or less, and particularly preferably 0.01 mol/L or more and 0.10 mol/L or less.

In the present specification, the term periodic acid (or an ion thereof) includes both orthoperiodic acid (or an ion thereof) and metaperiodic acid (or an ion thereof), unless otherwise specified.

In addition, periodic acid is ionized when dissolved in water, and therefore the periodate ions can be added in the form of a salt. Orthoperiodic acid is a stable composition not containing a metal such as Na, and therefore is more preferable than metaperiodic acid.

From the viewpoint of the efficiency of ruthenium silicide removal, the semiconductor treatment liquid preferably contains at least one selected from the group consisting of hypochlorous acid and a hypochlorite ion.

The halogen oxyacid and/or halogen oxyacid ion selected as the oxidizing agent contained in the semiconductor treatment liquid of the present embodiment can be one type or two or more types. When a plurality of types are contained, there is a possibility that the etching rate is stabilized and the stability at the time of reuse is improved. For example, in a case in which a hypobromite ion is contained as a first type of halogen oxyacid ion, a bromide ion is generated when consumption by oxidation or decomposition by disproportionation proceeds. A decrease in the concentration of the halogen oxyacid ions causes a decrease in the etching rate.

However, when the treatment liquid contains a hypochlorite ion as a second type of halogen oxyacid ion, the generated bromide ion can be oxidized and converted once again to a hypobromite ion. Stabilization of the etching rate is thereby facilitated.

For the reasons described above, in a case in which the semiconductor treatment liquid of the present embodiment contains a hypobromite ion, a hypochlorite ion preferably coexists. When a hypobromite ion and a hypochlorite ion coexist, the concentration of the hypochlorite ion is not limited as long as the spirit of the present invention is observed, but the concentration thereof is preferably 0.001 mol/L or more and 1.0 mol/L or less. When the concentration of the hypochlorite ion is 0.001 mol/L or more, Br⁻ can be efficiently oxidized, and maintaining the efficiency of ruthenium silicide removal (the etching rate) is facilitated. On the other hand, when the content of the hypochlorite ion is 1.0 mol/L or less, the stability of the hypochlorite ion is easily maintained, and decomposition of the hypobromite ion due to a reaction between the hypochlorite ion and the hypobromite ion is easily suppressed. The concentration of the hypochlorite ion is more preferably 0.001 mol/L or more and 1.0 mol/L or less and most preferably 0.01 mol/L or more and 0.5 mol/L or less.

For the same reason, specific examples of combinations of oxidizing agents coexisting in the semiconductor treatment liquid preferably include a combination of a hypochlorite ion and a hypobromite ion, a combination of hypochlorous acid and hypobromous acid, a combination of a hypochlorite ion and an orthoperiodate ion, a combination of a hypobromite ion and an orthoperiodate ion, a combination of hypochlorous acid and orthoperiodic acid, a combination of hypobromous acid and orthoperiodic acid, a combination of a hypochlorite ion and orthoperiodic acid, a combination of a hypobromite ion and orthoperiodic acid, a combination of hypochlorous acid and an orthoperiodate ion, and a combination of hypobromous acid and an orthoperiodate ion, and from the viewpoint of stability, specific examples of combinations of oxidizing agents coexisting in the semiconductor treatment liquid more preferably include a combination of a hypochlorite ion and a hypobromite ion, and a combination of hypochlorous acid and hypobromous acid.

Depending on the respective acid dissociation constants and the pH of the treatment liquid, the above-mentioned halogen oxyacids and ions thereof may coexist in the treatment liquid in the form of an acid (for example, HBrO) and in the form of an ion (for example, BrO⁻) in the treatment liquid according to chemical equilibrium. When the halogen oxyacid and the corresponding ion coexist in the treatment liquid, the total concentration of the acid form and the ion form can be regarded as the preferable ion concentration described above.

The method of incorporating the oxidizing agent into the semiconductor treatment liquid is not particularly limited, and the oxidizing agent can be added in the form of an aqueous solution containing the halogen oxyacid, the oxidizing agent can be generated by blowing a halogen gas into the treatment liquid, or a salt containing the halogen oxyacid ion as an anion can be added to the treatment liquid. From the viewpoints of ease of preparation of the treatment liquid and adjusting the pH, the oxidizing agent is preferably added in the form of a salt of an organic alkali and a halogen oxyacid, and is more preferably added in the form of a salt of a tetraalkylammonium hydroxide and a halogen oxyacid.

### (Decomposition Product)

The treatment liquid of the present embodiment can contain at least one type of ion selected from the group consisting of a bromide ion, a bromite ion, a bromate ion, a chloride ion, a chlorite ion, a chlorate ion, an iodide ion, a triiodide ion, and an iodate ion. These ions are decomposition products of the respective halogen oxyacid ions, and can be generated in the liquid over time. In particular, during the production of hypochlorous acid and hypobromous acid, an equal amount of chloride ions or bromide ions is generated with the hypochlorite ions or hypobromite ions. The concentration of these ions is not particularly limited, but in terms of a specific range, these ions are preferably contained in the semiconductor treatment liquid at a concentration in a range of 0.0001 mol/L or more and 5.0 mol/L or less, and in consideration of the stability of the halogen oxyacid ions, the concentration is more preferably in a range of 0.001 mol/L or more and 3.0 mol/L or less.

(pH)

The pH of the semiconductor treatment liquid of the present embodiment is preferably within a range of 0.0 to 10.0, which is a pH range in which hydrogen fluoride can stably exist. Furthermore, the pH value is more preferably 0.0 to 5.5, which is a pH range in which hydrogen fluoride can more stably exist. As the pH increases, the amount of hydrogen fluoride that can be present in the treatment liquid decreases, and thus the etching rate tends to decrease, whereas roughness of the surface of the substrate to be treated is easily suppressed.

Moreover, a preferable pH range according to the selected halogen oxyacid or ion thereof exists even within this range.

For example, in a case in which one or more of any of hypobromous acid, hypochlorous acid, and ions thereof are selected as the halogen oxyacid or ion thereof, the pH is preferably 2.0 or higher because decomposition of these acids or ions is easily suppressed. Therefore, in a case in which one or more of hypobromous acid, hypochlorous acid, and ions thereof are selected as the halogen oxyacid or ion thereof, the pH of the semiconductor treatment liquid is preferably in a pH range of 2.0 to 10.0, and more preferably in a pH range of 2.0 to 5.5.

In a case in which a periodate ion is contained as the halogen oxyacid ion in the semiconductor treatment liquid of the present embodiment, from the viewpoints of dissolving ability, smoothness, and the stability of the etching performance, the pH of the semiconductor treatment liquid is preferably in a pH range of 0.0 to 8.0, and more preferably in a pH range of 0.0 to 5.5.

In addition, in the present specification, the pH is a value at 25° C.

(Hydrogen Fluoride and/or Fluoride Ion)

The semiconductor treatment liquid according to the present embodiment contains hydrogen fluoride and/or fluoride ions. That is, the semiconductor treatment liquid contains both hydrogen fluoride and fluoride ions, or contains hydrogen fluoride or fluoride ions.

Hydrogen fluoride or fluoride ions have an effect of increasing the ruthenium silicide removal efficiency (etching rate) by dissolving, as hexafluorosilicate ions, the silicon oxide that is a surface oxide film of the ruthenium silicide and the silicon oxide in the ruthenium silicide oxidized by the oxidizing agent.

The method of incorporating the hydrogen fluoride or fluoride ions into the semiconductor treatment liquid is not particularly limited, and for example, the hydrogen fluoride or fluoride ions can be added in the form of an aqueous solution of hydrogen fluoride (hydrofluoric acid), a salt containing a fluoride ion as an anion can be added into the treatment liquid, or an aqueous solution in which an alkali compound is neutralized with hydrofluoric acid can be added. From the viewpoint of facilitating preparation of the treatment liquid, the hydrogen fluoride or fluoride ions are preferably added in the form of a fluoride of an onium salt (onium fluoride salt) described below. When fluoride ions are added in the form of a salt, some or all of the fluoride ions become hydrogen fluoride (HF) or hydrogen bifluoride ions (HF₂⁻) due to chemical equilibrium. Since HF or HF₂⁻ and the oxidizing agent are simultaneously present in the semiconductor treatment liquid, the ruthenium silicide can be etched.

The total concentration of the hydrogen fluoride and fluoride ions contained in the semiconductor treatment liquid is not particularly limited, but from the viewpoint of increasing the ruthenium silicide removal efficiency, the total concentration thereof as a fluoride element amount is preferably 0.001 mol/L or more and 10.0 mol/L or less, more preferably 0.005 mol/L or more and 5.0 mol/L or less, and particularly preferably 0.01 mol/L or more and 2.0 mol/L or less.

### (Onium Ion)

The semiconductor treatment liquid of the present embodiment contains an onium ion.

As a method of adding an onium ion to the semiconductor treatment liquid, an arbitary onium salt can be directly added, or an aqueous solution in which an organic alkali containing an onium ion is neutralized with an acid can be added as a salt.

From the viewpoint of easy preparation of the treatment liquid, the onium ion is preferably added to the semiconductor treatment liquid in the form of a salt with the above-mentioned fluoride ion, that is, in the form of an onium fluoride salt.

When the semiconductor treatment liquid contains an onium ion, damage to the silicon substrate can be suppressed. This is considered to be possible because the onium ions are adsorbed on the surface of the silicon substrate by hydrophobic interaction, and thereby etching by hydrogen fluoride is inhibited, and damage can be suppressed.

Examples of such onium ions or onium salts serving as a supply source of onium ions include at least one selected from the group consisting of a tetramethyl ammonium ion, a tetraethyl ammonium ion, a tetrapropyl ammonium ion, a chlorocholine ion, a trans-2-butene-1,4-bis(triphenylphosphonium ion), a 1-hexyl-3-methylimidazolium ion, an allyltriphenylphosphonium ion, a tetraphenylphosphonium ion, a benzyltriphenylphosphonium ion, a methyltriphenylphosphonium ion, a (2-carboxyethyl)triphenylphosphonium ion, a (3-carboxypropyl)triphenylphosphonium ion, a (4-carboxybutyl)triphenylphosphonium ion, a (5-carboxypentyl)triphenylphosphonium ion, a cinnamyltriphenylphosphonium ion, a (2-hydroxybenzyl)triphenylphosphonium ion, a (1-naphthylmethyl)triphenylphosphonium ion, a butyltriphenylphosphonium ion, a (tert-butoxycarbonylmethyl)triphenylphosphonium ion, an allyltriphenylphosphonium ion, a (3-methoxybenzyl)triphenylphosphonium ion, a (methoxymethyl)triphenylphosphonium ion, a (1-ethoxy-1-oxopropan-2-yl)triphenylphosphonium ion, a (3,4-dimethoxybenzyl)triphenylphosphonium ion, a methoxycarbonylmethyl(triphenyl)phosphonium ion, a (2,4-dichlorobenzyl)triphenylphosphonium ion, a (2-hydroxy-5-methylphenyl)triphenylphosphonium ion, a (4-chlorobenzyl)triphenylphosphonium ion, a (3-chloro-2-hydroxypropyl)trimethylammonium ion, a methacroylcholine ion, a benzoylcholine ion, a benzyldimethylphenylammonium ion, a (2-methoxyethoxymethyl)triethylammonium ion, a carbamylcholine ion, a 1,1′-difluoro-2,2′-bipyridinium bis(tetrafluoroborate), a benzyltributylammonium ion, a trimethylphenylammonium ion, a 5-azoniaspiro[4.4]nonane ion, a tributylmethylammonium ion, a tetrabutylammonium ion, a tetrapentylammonium ion, a tetrabutylphosphonium ion, a diallyldimethylammonium ion, a 1,1-dimethylpiperidinium ion, a (2-hydroxyethyl)dimethyl(3-sulfopropyl)ammonium hydroxide, a 3-(trifluoromethyl)phenyltrimethylammonium ion, a 1,1′-(decane-1,10-diyl)bis[4-aza-1-azoniabicyclo[2.2.2]octane] diion, a (3-bromopropyl)trimethylammonium ion, a vinylbenzyltrimethylammonium ion, an allyltrimethylammonium ion, a trimethylvinylammonium ion, a choline ion, a β-methylcholine ion, and a triphenylsulfonium ion, and salts thereof.

As the onium ion, one or more types selected from the group consisting of onium ions represented by the following Formulae (1) to (6) are preferably selected.

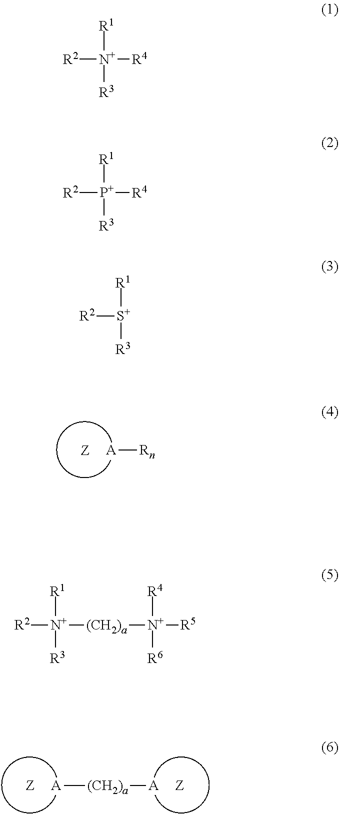

In Formula (1) to Formula (6),
R¹, R², R³, R⁴, R⁵, and R⁶ each independently represent an alkyl group having a carbon number from 1 to 9 (preferably from 1 to 3), an allyl group, an aralkyl group having an alkyl group with a carbon number from 1 to 9 (preferably from 1 to 3), or an aryl group. Moreover, in an aryl group of the aralkyl group and in a ring of the aryl group, at least one hydrogen is optionally substituted with fluorine, chlorine, an alkyl group having a carbon number from 1 to 9 (preferably from 1 to 3), an alkenyl group having a carbon number from 2 to 9 (preferably from 2 to 3), an alkoxy group having a carbon number from 1 to 9 (preferably from 1 to 3), or an alkenyloxy group having a carbon number from 2 to 9 (preferably from 2 to 3), and in these groups, at least one hydrogen is optionally substituted with fluorine, chlorine, bromine, or iodine.

A represents an ammonium ion, a phosphonium ion, or an arsonium ion.

Z represents an aromatic group or alicyclic group optionally containing a nitrogen, sulfur, or oxygen atom, and in the aromatic group or alicyclic group, a carbon or nitrogen optionally has chlorine, bromine, fluorine, iodine, at least one alkyl group having a carbon number from 1 to 9, at least one alkenyloxy group having a carbon number from 2 to 9, an aromatic group optionally substituted with at least one alkyl group having a carbon number from 1 to 9, or an alicyclic group optionally substituted with at least one alkyl group having a carbon number from 1 to 9.

R represents chlorine, bromine, fluorine, iodine, an alkyl group having a carbon number from 1 to 9, an allyl group, an aromatic group optionally substituted with at least one alkyl group having a carbon number from 1 to 9, or an alicyclic group optionally substituted with at least one alkyl group having a carbon number from 1 to 9. Moreover, n is an integer of 1 or 2 and represents the number of R. When n is 2, the R moieties are optionally identical or different and optionally form a ring. Furthermore, a is an integer of 1 to 10 (preferably 6 to 10).

Specific examples of the onium ions represented by Formulae (1) to (6) include at least one selected from the group consisting of an ammonium ion, a tetraalkylammonium cation, a tetraalkylphosphonium cation, a tetraalkylarsonium cation, a trialkylsulfonium cation, a hydrazinium dication, a diazenium dication, and a diazonium dication. At least one onium ion selected from the group consisting of a tetraalkylammonium cation, a tetraalkylphosphonium cation, a tetraalkylarsonium cation, a trialkylsulfonium cation, and a hydrazinium dication is preferable because such onium ions are not easily decomposed by a halogen oxyacid ion. Moreover, at least one onium ion selected from the group consisting of a tetraalkylammonium cation, a tetraalkylphosphonium cation, and a tetraalkylarsonium cation is more preferable because such onium ions have a property of being easily adsorbed on a silicon substrate through hydrophobic interaction, and a tetraalkylammonium cation is even more preferable because such onium ion is less likely to be adsorbed to ruthenium silicide.

Specific examples of the tetraalkylammonium cation include at least one selected from the group consisting of a tetramethylammonium cation, a tetraethylammonium cation, a tetrapropylammonium cation, a tetrabutylammonium cation, and a tetrapentylammonium cation, preferably at least one selected from the group consisting of a tetramethylammonium cation, a tetraethylammonium cation, and a tetrapropylammonium cation from the viewpoint of adsorption to a silicon substrate and the etching rate of ruthenium silicide, and more preferably at least one selected from the group consisting of a tetramethylammonium cation and a tetraethylammonium cation from the viewpoint of resistance to oxidation by a halogen oxyacid.

As the chain length of the alkyl group of the tetraalkylammonium cation increases, the roughness of the substrate can be suppressed, but the etching rate of ruthenium silicide tends to decrease.

The total concentration of the onium ions contained in the semiconductor treatment liquid is not particularly limited, but from the perspective of the balance between the efficiency of ruthenium silicide removal and the suppression of damage to the silicon substrate, the total concentration thereof is preferably 0.001 mol/L or more and 10.0 mol/L or less, more preferably 0.005 mol/L or more and 5.0 mol/L or less, and particularly preferably 0.01 mol/L or more and 2.0 mol/L or less.

In a case in which the onium ions, and the hydrogen fluoride and/or fluoride ions are added in the form of an onium fluoride salt into the semiconductor treatment liquid, the content of the onium fluoride salt is preferably 0.001 mol/L or more and 10.0 mol/L or less from the viewpoint of the etching rate of ruthenium silicide, is preferably 0.01 mol/L or more and 5.0 mol/L or less from the viewpoint of the etching rate of ruthenium silicide and damage to the silicon substrate, and is more preferably 0.05 mol/L or more and 2.0 mol/L or less because at such content, the ruthenium silicide can be etched more efficiently without damaging the silicon substrate.

Note that the concentration of each ion in the semiconductor treatment liquid can be confirmed using a known method. For example, absorption attributed to a hypohalite ion can be easily confirmed using ultraviolet-visible absorption spectroscopy, and the concentration of each ion can be determined from the intensity of the absorption peak thereof (generally near 330 nm if a hypobromite ion for example, although this depends on details such as the pH of the treatment liquid and the concentration of each ion). The concentration of each ion can also be determined by a titration method, an oxidation-reduction potential, a chromatograph, or the like.

### (Other Components)

The semiconductor treatment liquid of the present embodiment can contain, as other components, known additives or the like that have been used in a semiconductor treatment liquid, within a scope that does not impair the object of the present invention. Examples of the additives that can be added include an acid other than those given as examples of the oxidizing agent above, a metal corrosion inhibitor, a water-soluble organic solvent, a fluorine compound other than the above hydrogen fluoride, a reducing agent, a complexing agent, a chelating agent, a surfactant, an antifoaming agent, a pH adjuster, and a stabilizer. A single type of these additives can be added alone, or a plurality of these additives can be added in combination.

As the pH adjuster, an acid or an alkali can be added to the semiconductor treatment liquid of the present embodiment. As the acid, an acid that does not contain a metal ion that is problematic in semiconductor production is preferably used, and examples thereof include at least one selected from the group consisting of hydrochloric acid, nitric acid, sulfuric acid, phosphoric acid, boric acid, acetic acid, toluenesulfonic acid, and methanesulfonic acid. As the alkali, an organic alkali is preferably used because such an alkali does not contain a metal ion that is problematic in semiconductor production. Among organic alkalis, from the viewpoint of providing a large number of hydroxide ions per unit weight and a high-purity product being readily available, and from the viewpoint of the organic alkali also being used as an onium ion supply source, the organic alkali is preferably a tetraalkylammonium hydroxide and more preferably tetramethylammonium hydroxide.

The semiconductor treatment liquid of the present embodiment preferably uses water as a solvent, and the water used as a solvent is preferably water from which metal ions, organic impurities, particles, and the like have been removed by distillation, ion exchange treatment, filtration, or any type of adsorption treatment, and pure water or ultrapure water is particularly preferable. Such water can be obtained by a known method widely used in semiconductor manufacturing.

The semiconductor treatment liquid of the present embodiment is preferably stored at a low temperature and/or under a light-shielded condition. Storage at a low temperature and/or under a light-shielded condition can be expected to provide an effect of inhibiting decomposition of the oxidizing agent in the semiconductor treatment liquid. Furthermore, the stability of the semiconductor treatment liquid can be maintained by storing the semiconductor treatment liquid in a container filled with an inert gas to prevent contamination of carbon dioxide. In addition, the inner surface of the container, that is, the surface that is in contact with the semiconductor treatment liquid, is preferably formed of an organic polymer material. This is because if the inner surface of the container is formed of an organic polymer material, the entrance of impurities, such as a metal, a metal oxide, and an organic material can be further reduced without being affected by hydrogen fluoride. Preferable examples of the organic polymer material include perfluoroalkoxy fluororesin (PFA), polyethylene (PE), and polypropylene (PP).

### <Method for Producing Semiconductor Treatment Liquid (Etching Solution)>

The method for obtaining the semiconductor treatment liquid of the present embodiment is not particularly limited, and a known method for producing a semiconductor treatment liquid can be appropriately applied. For example, solutions containing the necessary components may be mixed. As the method for mixing each solution, for example, a method using a mixing tank, a method of mixing in piping of a semiconductor manufacturing apparatus (in-line mixing), or a method of mixing by simultaneously pouring a plurality of solutions onto a substrate can be suitably used.

More specifically, the semiconductor treatment liquid can be obtained, for example, by the following method.

First, a solution serving as a supply source of onium ions (for example, an aqueous solution of alkyl onium hydroxide) is prepared in a sealable container. Next, a halogen gas or a liquid halogen is supplied to the container to obtain a mixed solution of an onium hypohalous oxyacid aqueous solution and an alkyl onium hydroxide. In this case, a step of discharging carbon dioxide in the gas phase portion by streaming an inert gas into the container can be included. The supply source of onium ions can also be prepared in the form of a salt (for example, an onium fluoride salt).

The semiconductor treatment liquid according to the present embodiment can be obtained by mixing a desired amount of other necessary components (such as, for example, hydrofluoric acid, a solvent, and a pH adjusting agent) into the prepared mixed solution of the onium hypohalous oxyacid aqueous solution and the alkyl onium hydroxide.

### (Ruthenium Silicide Etching Method)

The semiconductor treatment liquid of the present embodiment can be used to etch the ruthenium silicide on a substrate. The etching method includes a step of bringing the substrate into contact with the semiconductor treatment liquid of the present embodiment. The substrate is not particularly limited as long as ruthenium silicide is present on the surface thereof, and is, for example, a semiconductor wafer.

Note that in the present specification, the semiconductor treatment liquid of the present embodiment is mainly described as an example in which the semiconductor treatment liquid is used as an etching solution for etching ruthenium silicide, but the present invention is not limited thereto as long as the purpose is to remove ruthenium silicide. For example, the semiconductor treatment liquid of the present embodiment can be used as a cleaning liquid, an etching solution for etching a residue after dry etching, an etching solution for a bevel and rear surface, or an etching solution for recess etching.

The semiconductor treatment liquid of the present embodiment can be preferably used as an etching solution for a semiconductor wafer.

An etching method in which etching is implemented using the treatment liquid of the present embodiment is hereinafter described using etching of a ruthenium silicide film laminated on a silicon substrate as an example. First, a substrate made of a semiconductor (e.g., Si) is prepared. The prepared substrate is subjected to a hydrofluoric acid treatment to remove the natural oxide film of silicon formed on the substrate. Subsequently, with ruthenium and silicon as targets, the ratio of ruthenium to silicon to be sputtered is set to 1:2, and the ruthenium and silicon are simultaneously laminated on the silicon substrate by the PVD method. The obtained ruthenium silicide (hereinafter, also referred to as RuSi₂) is subjected to an etching treatment by being brought into contact with the semiconductor treatment liquid according to the present embodiment, and thereby the ruthenium silicide is completely removed.

The semiconductor wafer to be etched can contain a metal other than ruthenium silicide. Specifically, the semiconductor wafer can contain at least one transition metal selected from the group consisting of Ru, Rh, Ti, Ta, Co, Cr, Hf, Os, Pt, Ni, Mn, Cu, Zr, La, Mo, and W. When a metal other than ruthenium silicide is contained, as necessary, the metal can be removed using a known semiconductor treatment liquid corresponding the respective metal.

The temperature at which the ruthenium silicide is etched using the semiconductor treatment liquid of the present embodiment is not particularly limited, and can be determined in consideration of details such as the etching rate of the ruthenium silicide. In a case in which the treatment temperature is high, the stability of the halogen oxyacid decreases. On the other hand, as the treatment temperature is decreased, the etching rate tends to be reduced. For such reasons, the temperature at which the ruthenium silicide is etched is preferably 10° C. to 90° C., more preferably 15° C. to 60° C., and most preferably 25° C. to 45° C.

### (Method of Manufacturing Semiconductor Element)

A semiconductor element can be manufactured by a method including a step of bringing the semiconductor treatment liquid of the present embodiment into contact with a semiconductor wafer containing ruthenium silicide, thereby etching the ruthenium silicide.

An example of a process for manufacturing a semiconductor element is described with reference to the FIGURE. In a case in which the manufacturing process includes a filtration step when manufacturing the semiconductor element, the semiconductor treatment liquid has an opportunity to pass through filters 1 and 2 or a filter 3. When a second valve 10 illustrated in the FIGURE is closed and a first valve 9 is opened, a chemical solution in a chemical cabinet 6 is filtered by being passed through the filters 1 and 2 by driving of a first pump 4. To remove as many impurities as possible from the chemical solution in the chemical cabinet 6, the filtration step of passing the chemical solution through the filters 1 and 2 can be carried out a plurality of times. The number of filters through which the chemical solution is passed in one filtration step is, for example, 1 or more and can be 2, 3, or 4 or more.

When the second valve 10 in the FIGURE is opened, the chemical solution in the chemical cabinet 6 is supplied to an etching table 8 by driving the first pump 4, and a semiconductor wafer is etched. To replenish the chemical solution in the chemical cabinet 6, the chemical solution in a chemical solution replenishing unit 7 is passed through the filter 3 by the driving of a second pump 5 and is replenished into the chemical cabinet 6.

The chemical solution described here can be the semiconductor treatment liquid itself, or can be a chemical solution obtained by adding a decomposition inhibitor to the semiconductor treatment liquid.

The method of manufacturing a semiconductor element can include a known step used in a method for manufacturing a semiconductor element, such as one or more steps selected from a wafer fabrication step, an oxide film formation step, a transistor formation step, a wiring formation step, and a CMP step.

Moreover, a semiconductor treatment liquid that has been used can be used in the method for manufacturing a semiconductor element.

Specifically, the method for manufacturing a semiconductor element can include a step of recovering the semiconductor treatment liquid after etching a semiconductor wafer, and a step of etching a semiconductor wafer using the recovered treatment liquid. The method for manufacturing a semiconductor element can also include a step of measuring the concentration of the oxidizing agent in the recovered treatment liquid.

### EXAMPLES

The present invention will be more specifically described below by examples, but the present invention is not limited to these Examples.

### <Raw Materials to Be Used>

The oxidizing agent used in the semiconductor treatment liquid of each Example and Comparative Example was produced by the following method.

### (Production of Tetramethylammonium Hypochlorite Solution)

In a 2-L three-necked flask (available from Cosmos Bead Co., Ltd.) made of glass, 209 g of a 25 mass % tetramethylammonium hydroxide aqueous solution (available from Tokuyama Corporation) was mixed with 791 g of ultrapure water, and a 5.2 mass % tetramethylammonium hydroxide aqueous solution with a CO₂ content of 0.5 ppm was obtained. The pH of this 5.2 mass % tetramethylammonium hydroxide aqueous solution at 25° C. was 13.8.

Next, a rotor (available from As One Corporation, full length 30 mm×diameter 8 mm) was inserted into the three-neck flask, and a thermometer protection tube (available from Cosmos Bead Co., Ltd.) and a thermometer were inserted into one opening of the flask. A PFA tube (available from Flon Industry Co., Ltd., F-8011-02) connected to a chlorine gas cylinder and a nitrogen gas cylinder and capable of arbitrarily switching between chlorine gas and nitrogen gas was inserted into another opening of the flask, and the tip end of the PFA tube was immersed in the bottom portion of the solution. The remaining one opening was connected to a gas washing bottle (available from As One Corporation, gas washing bottle, model number 2450/500) filled with a 5 mass % aqueous sodium hydroxide solution. Next, nitrogen gas with a carbon dioxide concentration of less than 1 ppm was streamed from the PFA tube at 0.289 Pa·m³/sec (when converted to 0° C.) for 20 minutes, and thereby carbon dioxide in the gas phase was purged, and the concentration of carbon dioxide in the gas phase was reduced to 1 ppm or less.

Subsequently, a magnetic stirrer (C-MAG HS10, available from As One Corporation) was placed in the bottom portion of the three-necked flask and rotated at 300 rpm to stir the contents, and while the periphery of the three-necked flask was cooled with ice water, chlorine gas (specification purity of 99.4%, available from Fujiox Co., Ltd.) was supplied at 0.059 Pa-m³/see (when converted to 0° C.) for 180 minutes, and a mixed solution 1 of a tetramethylammonium hypochlorite aqueous solution (hypochlorite ion; 3.51 mass % equivalent, 0.28 mol/L) and tetramethylammonium hydroxide (0.09 mass % equivalent, 0.0097 mol/L) was obtained. At this time, the solution temperature during the reaction was 11° C.

### (Halogen Oxyacid Ion in Treatment Liquid)

When hypochlorous acid and/or hypochlorite ions were selected as the oxidizing agent, the mixed solution 1 obtained by the above operation was used as the oxidizing agent (TMAClO in the table) at a predetermined concentration.

When hypobromous acid and/or hypobromite ions were selected as the oxidizing agent, a predetermined amount of tetramethylammonium bromide (97 mass %, available from Tokyo Chemical Industry Co., Ltd.) was added to the mixed solution 1 obtained through the above operation, and the resultant solution was used as the oxidizing agent (TMABrO in the table) at a predetermined concentration.

When periodate ions were selected as the oxidizing agent, commercially available orthoperiodate (available from Fujifilm Wako Pure Chemical Corp.) was used as the oxidizing agent at a predetermined concentration.

The following raw materials were used as other raw materials used in the semiconductor treatment liquid of each Example and Comparative Example.
TMAH: 25 wt. % tetramethylammonium hydride (SD-25, available from Tokuyama Corporation)
TEAH: 35 wt. % tetraethylammonium hydride (available from Tokyo Chemical Industry Co., Ltd.)
TPAH: 40 wt. % tetrapentylammonium hydride (available from Tokyo Chemical Industry Co., Ltd.)
TBAH: 40 wt. % tetrabutylammonium hydride (available from Tokyo Chemical Industry Co., Ltd.)
TMAF: 15 wt. % tetramethylammonium fluoride aqueous solution (available from Tokyo Chemical Industry Co., Ltd.)
TEAF: 15 wt. % tetraethylammonium fluoride aqueous solution (available from Tokyo Chemical Industry Co., Ltd.)
TBAF: 15 wt. % tetrabutylammonium fluoride aqueous solution (available from Tokyo Chemical Industry Co., Ltd.)
HF: 49 wt. % hydrofluoric acid (available from Fujifilm Wako Pure Chemical Corp.)
Ca(ClO)₂: calcium hypochlorite (available from Fujifilm Wako Pure Chemical Corp.)
Hydrogen peroxide: 30 wt. % hydrogen peroxide (available from Fujifilm Wako Pure Chemical Corp.)

### (Method for Calculating Total Concentration of Hypochlorous Acid, Hypobromous Acid, and Ions Thereof)

The total concentration of hypochlorous acid, hypobromous acid, and ions thereof was measured using an ultraviolet-visible spectrophotometer (V-750, available from JASCO Corporation). A calibration curve was prepared using an aqueous hypobromite ion solution and an aqueous hypochlorite ion solution having known concentrations, and the hypobromite ion and hypochlorite ion concentrations in the produced semiconductor treatment liquid were determined. The concentrations of these acids were also calculated in the same manner from calibration curves of an aqueous hypobromous acid solution and an aqueous hypochlorous acid solution having known concentrations. Note that the concentrations of these acids and ions were determined from measurement data when the absorption spectrum stabilized after mixing the various raw materials.

### (Method for Calculating Periodic Acid and Periodate Ion Concentrations)

The concentrations of periodic acid and periodate ions were calculated from the charged amount of orthoperiodate used as a raw material.

### (Method for Calculating Onium Ion Concentration)

The onium ion concentration was measured and calculated using an ion chromatograph (Integrion, available from Thermo Fisher Scientific Inc.). After the treatment liquids of the Examples and Comparative Examples were prepared, 1 g of a treatment liquid was added to a 100 mL volumetric flask, and ultrapure water was poured into the flask to the scale line to obtain a measurement liquid of each treatment liquid diluted 100-fold. Next, a calibration curve for each onium ion was prepared by the same procedure using each onium ion. The prepared measurement liquid was measured using a cation measurement mode of an ion chromatograph. From the obtained peak area value, the onium ion concentration was calculated based on the peak area value of the calibration curve prepared in advance.

### (Method for Calculating Hydrogen Fluoride and Fluoride Ion Concentrations)

The hydrogen fluoride concentration was calculated from the charged amount. The fluoride ion concentration was measured and calculated using an ion chromatograph (Integrion, available from Thermo Fisher Scientific Inc.). After the treatment liquids of the Examples and Comparative Examples were prepared, 1 g of a treatment liquid was added to a 100 mL volumetric flask, and ultrapure water was poured into the flask to the scale line to obtain a measurement liquid of each treatment liquid diluted 100-fold. Next, a fluoride ion calibration curve was prepared by the same procedure using a 1000 ppm fluoride ion standard solution (available from Fujifilm Wako Pure Chemical Corp.). The prepared measurement liquid was measured in an anion measurement mode of an ion chromatograph. The fluoride ion peak was close to the water dip, and therefore a gradient was applied to obtain the fluoride ion peak. From the obtained peak area value, the fluoride ion concentration was calculated based on the peak area value of the calibration curve prepared in advance.

(pH)

The pH of each of the treatment liquids prepared in the Examples and Comparative Examples was measured using 10 mL of the treatment liquid and a tabletop pH meter (LAQUA F-73, available from Horiba, Ltd.). The pH was measured after the treatment liquid was prepared and stabilized at 25° C.

### (Preparation of Treatment Liquid)

### Examples 1 to 20 and Comparative Examples 1 to 6

The raw materials described above were mixed in accordance with the compositions described in Table 1, and ultrapure water was added thereto to obtain a total amount of 100 parts by mass, and thereby the semiconductor treatment liquids of Examples 1 to 20 and Comparative Examples 1 to 6 were prepared.

### (Evaluation of Etching Rate (ER))

An amount of 40 mL of the prepared treatment liquid was measured and inserted into a 100 mL container made of PFA, and then stirred at 1000 rpm using a magnetic stirrer (C-MAG HS10, available from As One Corporation) installed at the lower part of the container. Subsequently, a 200 nm ruthenium silicide (RuSi₂) film and a 100 nm single crystal silicon film having a lattice plane of (100) (hereinafter, also referred to as a Si (100) film) were inserted into each treatment liquid, and an etching treatment was carried out for 1 minute. After the etching treatment, the films were thoroughly rinsed with ultrapure water and thoroughly dried by blowing with N₂. The film thicknesses of the ruthenium silicide before and after the etching treatment were evaluated by fluorescent X-ray analysis (ZSX Primus IV, available from RIGAKU Corporation). The film thicknesses of the Si (100) film before and after the etching treatment were evaluated by spectroscopic ellipsometry (M-2000, available from J. A. Woollam Japan Corp.).

### (Evaluation of Surface State of Si (100) Film)

The surface states before and after etching of the 100 nm Si (100) film used in the etching rate evaluation were observed using a field emission scanning electron microscope (Regulus 8230, available from Hitachi High-Tech Corporation) to confirm the presence or absence of surface roughness, and the surface states were evaluated according to the following criteria.
A: No surface roughness was observed.
B: Surface roughness was slightly observed.
C: Roughness was observed on the entire surface, but the roughness was shallow.
D: Roughness was observed on the entire surface, and the roughness was deep.

### Evaluation Results

The results of these evaluations are presented in Table 2.

In Comparative Example 1, the etching rate of ruthenium silicide was very high, but the surface state of the Si film after the etching treatment was poor, and whitening was visually confirmed. On the other hand, in Examples 1 to 20, the ruthenium silicide was successfully etched while suppressing a deterioration in the surface state.

Moreover, in a comparison of Examples 1 to 5, it can be confirmed that the etching rate tends to decrease as the pH of the treatment liquid increases.

Comparative Examples 2 to 4 are typical compositions of treatment liquids that can etch ruthenium. With these treatment liquids, ruthenium can be etched, but ruthenium silicide cannot be etched. Similarly, as exhibited in Comparative Example 5, ruthenium silicide cannot be etched with hydrofluoric acid alone.

In a comparison of Examples 2, 6, and 7, it can be confirmed that the etching rate of ruthenium silicide tends to decrease as the amount of the oxidizing agent decreases.

Moreover, in a comparison of Examples 2 and 8 to 10, it can be confirmed that the etching rate of ruthenium silicide tends to increase as the amount of fluoride ions increases.

In a comparison of Examples 2 and 11 to 18, it can be confirmed that the etching rate of ruthenium silicide tends to change due to a difference in the onium ion. In each of Examples 2 and 11 to 13, an organic alkali was used as the onium ion supply source, but the chain length of the alkyl group of the quaternary ammonium cation differed in each example. It was confirmed that the surface state of the Si (100) film can be more smoothly maintained as the chain length of the alkyl group increases, but at the same time, the etching rate of ruthenium silicide tends to be suppressed.

Examples 14 to 16 are examples in which a fluoride salt of a tetraalkylammonium was used as the supply source of onium ions and fluoride ions. Even in the case of the fluoride salt of tetraalkylammonium, the results were nearly similar to those obtained when the organic alkali and hydrofluoric acid were each added as indicated in Examples 8 to 13. Therefore, it is understood that as the supply source of onium ions and fluoride ions, a mixture of an organic alkali and hydrofluoric acid can be used, or an onium salt having a fluoride ion as an anion can be used.

Examples 2, 19, and 20 exhibited differences in the etching rate of ruthenium silicide due to differences in the oxidizing agent. Here, it was confirmed that ruthenium silicide can be suitably etched even when the oxidizing agent is any of hypochlorous acid, hypobromous acid, and periodic acid.

However, as demonstrated in Comparative Example 6, ruthenium silicide cannot be etched when hydrogen peroxide is used as the oxidizing agent. Further, since hydrogen peroxide has a low oxidation-reduction potential (ORP), the ruthenium in the ruthenium silicide was oxidized to RuO₂, and the surface was blackened and contaminated.

TABLE 1
Liquid Composition

| | | | | | | | Total | Total | |
|---|---|---|---|---|---|---|---|---|---|
| | Oxidizing Agent | | Onium Ion | | Fluoride Ion | | Onium Ion | Fluoride Ion | |
| | Supply Source | | Supply Source | | Supply Source | | Molar | Molar | |
| | | parts | | parts | | parts | Concen- | Concen- | |
| | | by | | by | | by | tration | tration | pH |
| | Name | mass | Name | mass | Name | mass | [mol/L] | [mol/L] | — |
| Example 1 | 0.3 mol/L TMAClO | 20.0 | 2.7 mol/L TMAH | 16.0 | 25.0 mol/L HF | 2.0 | 0.55 | 0.50 | 1.0 |
| Example 2 | 0.3 mol/L TMAClO | 20.0 | 2.7 mol/L TMAH | 19.5 | 25.0 mol/L HF | 2.0 | 0.65 | 0.50 | 3.0 |
| Example 3 | 0.3 mol/L TMAClO | 20.0 | 2.7 mol/L TMAH | 19.6 | 25.0 mol/L HF | 2.0 | 0.65 | 0.50 | 5.0 |
| Example 4 | 0.3 mol/L TMAClO | 20.0 | 2.7 mol/L TMAH | 19.7 | 25.0 mol/L HF | 2.0 | 0.65 | 0.50 | 10.0 |
| Example 5 | 0.3 mol/L TMAClO | 20.0 | 2.7 mol/L TMAH | 20.0 | 25.0 mol/L HF | 2.0 | 0.66 | 0.50 | 12.0 |
| Example 6 | 0.3 mol/L TMAClO | 10.0 | 2.7 mol/L TMAH | 20.0 | 25.0 mol/L HF | 2.0 | 0.60 | 0.50 | 3.0 |
| Example 7 | 0.3 mol/L TMAClO | 5.0 | 2.7 mol/L TMAH | 20.5 | 25.0 mol/L HF | 2.0 | 0.58 | 0.50 | 3.0 |
| Example 8 | 0.3 mol/L TMAClO | 20.0 | 2.7 mol/L TMAH | 29.7 | 25.0 mol/L HF | 3.0 | 0.92 | 0.75 | 3.0 |
| Example 9 | 0.3 mol/L TMAClO | 20.0 | 2.7 mol/L TMAH | 40.1 | 25.0 mol/L HF | 4.0 | 1.20 | 1.00 | 3.0 |
| Example 10 | 0.3 mol/L TMAClO | 20.0 | 2.7 mol/L TMAH | 60.8 | 25.0 mol/L HF | 6.0 | 1.76 | 1.50 | 3.0 |
| Example 11 | 0.3 mol/L TMAClO | 20.0 | 2.4 mol/L TEAH | 22.5 | 25.0 mol/L HF | 2.0 | 0.66 | 0.50 | 3.0 |
| Example 12 | 0.3 mol/L TMAClO | 20.0 | 2.0 mol/L TPAH | 27.2 | 25.0 mol/L HF | 2.0 | 0.66 | 0.50 | 3.0 |
| Example 13 | 0.3 mol/L TMAClO | 20.0 | 1.5 mol/L TBAH | 34.8 | 25.0 mol/L HF | 2.0 | 0.64 | 0.50 | 3.0 |
| Example 14 | 0.3 mol/L TMAClO | 20.0 | 1.6 mol/L TMAF | 33.5 | Same as left | Same as left | 0.66 | 0.54 | 3.0 |
| Example 15 | 0.3 mol/L TMAClO | 20.0 | 1.0 mol/L TEAF | 54.0 | Same as left | Same as left | 0.66 | 0.54 | 3.0 |
| Example 16 | 0.3 mol/L TMAClO | 20.0 | 0.6 mol/L TBAF | 80.0 | Same as left | Same as left | 0.60 | 0.48 | 3.0 |
| Example 17 | 0.3 mol/L TMAClO | 40.0 | 1.6 mol/L TMAF | 33.5 | 25.0 mol/L HF | 1.0 | 0.78 | 0.79 | 1.0 |
| Example 18 | 0.3 mol/L TMAClO | 40.0 | 1.0 mol/L TEAF | 54.0 | 25.0 mol/L HF | 1.0 | 0.78 | 0.79 | 1.0 |
| Example 19 | 0.1 mol/L TMABrO | 40.0 | 2.7 mol/L TMAH | 19.5 | 25.0 mol/L HF | 2.0 | 0.65 | 1.03 | 3.0 |
| Example 20 | Orthoperiodate | 1.0 | 2.7 mol/L TMAH | 19.5 | 25.0 mol/L HF | 2.0 | 0.53 | 1.03 | 3.0 |
| Comparative Example 1 | 0.3 mol/L Ca(ClO)₂ | 20.0 | — | — | 25.0 mol/L HF | 2.0 | — | 0.50 | 1.0 |
| Comparative Example 2 | 0.3 mol/L TMAClO | 20.0 | — | — | — | — | 0.12 | — | 12.0 |
| Comparative Example 3 | 0.1 mol/L TMABrO | 40.0 | — | — | — | — | 0.12 | — | 12.0 |
| Comparative Example 4 | Orthoperiodate | 1.0 | — | — | — | — | — | — | 8.0 |
| Comparative Example 5 | — | — | — | — | 25.0 mol/L HF | 2.0 | — | 0.50 | 0.0 |
| Comparative Example 6 | 30 wt. % H2O2 | 10.0 | — | — | 25.0 mol/L HF | 2.0 | — | 0.50 | 0.0 |

TABLE 2

| | Evaluation Results | | | |
|---|---|---|---|---|
| | | | | Etching |
| | RuSi₂ | Si (100) Film | | Selection |
| | Film | | Surface | Ratio |
| | ER | ER | Observation | (RuSi₂/Si) |
| | [nm/min] | [nm/min] | Evaluation | — |
| Example 1 | 22 | 10.1 | B | 2.2 |
| Example 2 | 41 | 10.3 | A | 4.0 |
| Example 3 | 24 | 10.2 | A | 2.4 |
| Example 4 | 1.1 | 1.9 | A | 0.6 |
| Example 5 | 0.1 | 0.2 | A | 0.5 |
| Example 6 | 20 | 4.8 | A | 4.2 |
| Example 7 | 11 | 2.7 | A | 4.1 |
| Example 8 | 48 | 15.4 | A | 3.1 |
| Example 9 | 55 | 21.1 | B | 2.6 |
| Example 10 | 44 | 33.2 | C | 1.3 |
| Example 11 | 36 | 8.8 | A | 4.1 |
| Example 12 | 32 | 7.5 | A | 4.3 |
| Example 13 | 26 | 5.3 | A | 4.9 |
| Example 14 | 40 | 10.3 | A | 3.9 |
| Example 15 | 35 | 8.7 | A | 4.0 |
| Example 16 | 26 | 5.2 | A | 5.0 |
| Example 17 | 18 | 8.5 | B | 2.1 |
| Example 18 | 15 | 7.2 | A | 2.1 |
| Example 19 | 21 | 10.2 | A | 2.1 |
| Example 20 | 13 | 10.0 | A | 1.3 |
| Comparative | 302 | 109.0 | D | 2.8 |
| Example 1 | | | | |
| Comparative | 0 | 2.0 | A | 0.0 |
| Example 2 | | | | |
| Comparative | 0 | 2.0 | A | 0.0 |
| Example 3 | | | | |
| Comparative | 0 | 0.1 | A | 0.0 |
| Example 4 | | | | |
| Comparative | 0 | 1.0 | A | 0.0 |
| Example 5 | | | | |
| Comparative | 0 | 10.1 | D | 0.0 |
| Example 6 | | | | |

### REFERENCE SIGNS LIST

1 Filter 1
2 Filter 2
3 Filter 3
4 First pump
5 Second pump
6 Chemical cabinet
7 Chemical solution replenishing unit
8 Etching table
9 First valve
10 Second valve

1. A semiconductor treatment liquid for removing ruthenium silicide from a substrate containing ruthenium silicide, the semiconductor treatment liquid comprising:
(i) at least one selected from the group consisting of hypochlorous acid, hypobromous acid, periodic acid, and ions thereof,
(ii) at least one selected from the group consisting of hydrogen fluoride and a fluoride ion; and
(iii) an onium ion.

2. The semiconductor treatment liquid according to claim 1, wherein the component (i) is at least one selected from the group consisting of hypochlorous acid and a hypochlorite ion.

3. The semiconductor treatment liquid according to claim 1, wherein a total concentration of the component (i) in the semiconductor treatment liquid is 0.001 mol/L to 0.50 mol/L in terms of halogen element content.

4. The semiconductor treatment liquid according to claim 1, wherein a total concentration of the component (ii) in the semiconductor treatment liquid is 0.001 mol/L to 10.0 mol/L in terms of fluorine element content.

5. The semiconductor treatment liquid according to claim 1, wherein a total concentration of the component (iii) in the semiconductor treatment liquid is 0.001 mol/L to 10.0 mol/L.

6. The semiconductor treatment liquid according to claim 1, wherein the semiconductor treatment liquid has a pH of 0.0 to 10.0 at 25° C.

7. The semiconductor treatment liquid according to claim 1, wherein the component (iii) is an onium ion represented by Formula (1): 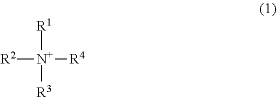
wherein,
R¹, R², R³, and R⁴ each independently represent an alkyl group having a carbon number from 1 to 9, an allyl group, an aralkyl group having an alkyl group having a carbon number from 1 to 9, or an aryl group;
at least one hydrogen of the aryl group in the aralkyl group and in the ring of the aryl group is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9; and
in these groups, at least one hydrogen is optionally substituted with fluorine, chlorine, bromine, or iodine.

8. A method for manufacturing a semiconductor element, the method comprising
bringing a substrate containing ruthenium silicide into contact with the semiconductor treatment liquid according to claim 1, thereby etching the ruthenium silicide.
